(19) United States
(12) Patent Application Publication
(10) Pub. No.: US 2007/0246750 A1
(43) Pub. Date: Oct. 25, 2007

(54) Control of body potential of partially-depleted field-effect transistors

(75) Inventor: Atsushi Azuma, Yokohama-city (JP)

Correspondence Address: BANNER & WITCOFF, LTD., 1100 13th STREET, N.W., SUITE 1200, WASHINGTON, DC, 20005-4051, US

(73) Assignee: Toshiba America Electronics Components, Inc., Irvine, CA (US)

(21) Appl. No.: 11/406,381

(22) Filed: Apr. 19, 2006

(51) Int. Cl. H01L 29/80

(52) U.S. Cl. 257/273

(57) ABSTRACT

A partially-depleted silicon-on-insulator (SOI) field-effect transistor (FET) with a reduced off-current is described, as well as methods for manufacturing. This may be accomplished by providing an SOI FET having a lower body potential than in previous SOI FETs. To lower the body potential, carrier traps may be formed mainly in the neutral source and drain regions of the SOI FET by extra over-etching of the gate spacers and the underlying silicon layer.

### BACKGROUND

The performance of partially-depleted silicon-on-insulator (SOI) field-effect transistors (FETs) are measured by a number of characteristics. One such characteristic is the off-current of a FET. The off-current is the amount of current that flows between the source and the drain of the FET when the FET is in the off state (i.e., when the gate of the FET is at a low potential). The lower the off-current, the better. Another characteristic is the energy barrier that electrons must overcome to flow from the source, through the channel, and into the drain.

Both of these characteristics are affected by the body potential of a FET. The body potential is the potential, or voltage, of the neutral region under the channel of the FET. As for the off-current, higher the body potential, the higher the off-current. Likewise, the energy barrier is decreased as the body potential rises. This means that the threshold turn-on voltage (Vth) is relatively low, such that the drain-to-source off current is relatively high. This phenomenon is known as drain-induced barrier lowering (DIBL). The higher the body potential, the greater the detrimental effect of DIBL.

Attempts have been made to reduce DIBL effects by implanting xenon (Xe) ions into the extension regions of FETs. The Xe ions cause a carrier trap to be generated in both the source/drain regions and in the depletion regions, thereby raising the barrier that electrons must overcome. However, this technique has so far been only moderately effective and does not significantly lower the body potential. Nor have such techniques had much effect on lowering the off-current.

### SUMMARY

There is a need for an improved way to reduce the off-current in a partially-depleted silicon-on-insulator (SOI) field-effect transistor (FET). This may be accomplished by providing an SOI FET having a lower body potential than in previous SOI FETs. The aspects discussed herein can work with a variety of SOI FETs, but may be particularly advantageous with shorter gate length SOI FETs, such as those with a gate length of less than 100 nm.

These and other aspects of the disclosure will be apparent upon consideration of the following detailed description of illustrative embodiments.

### BRIEF DESCRIPTION OF THE DRAWINGS

A more complete understanding of the present invention and the advantages thereof may be acquired by referring to the following description in consideration of the accompanying drawings, in which like reference numbers indicate like features, and wherein:

FIG. 1 is a side cross-sectional view of an illustrative FET.

FIG. 2 is a graph indicating current across a P/N semiconductor junction with a higher body voltage.

FIG. 3 is a graph indicating current across a P/N semiconductor junction with a lower body voltage.

FIG. 4 is a side cross-sectional view of an illustrative FET configured to have a relatively lower body voltage.

FIG. 5 is a graph indicating forward junction current versus reverse junction current for two FETs having different body voltages.

FIG. 6 is a graph indicating drive current versus off current for two FETs having different body voltages.

FIG. 7 is a flowchart showing illustrative steps that may be taken to manufacture a FET semiconductor device having a relatively lower body voltage.

### DETAILED DESCRIPTION OF ILLUSTRATIVE EMBODIMENTS

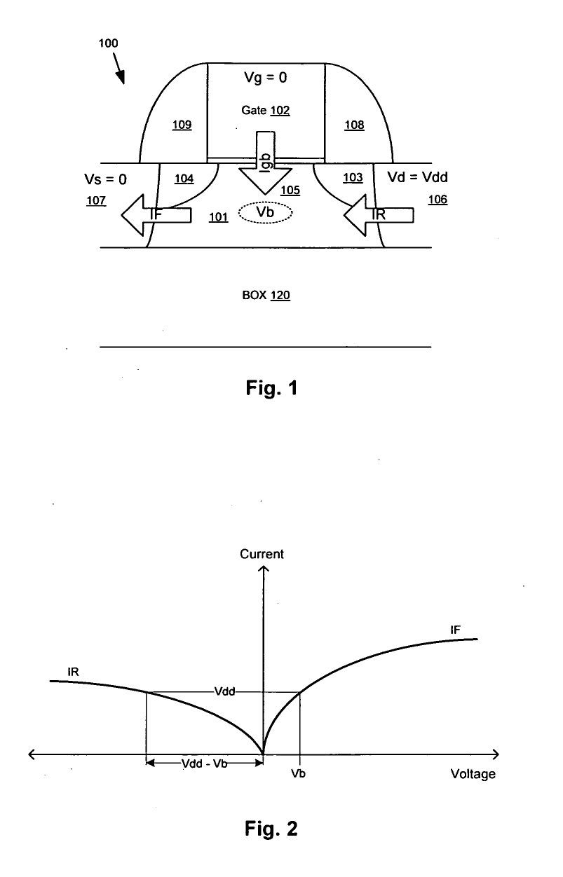

Referring to FIG. 1, an illustrative semiconductor device including a partially-depleted field-effect transistor (FET) 100 is shown. FET 100, which may be an NFET or a PFET, is formed in and on a silicon layer 101. Silicon layer 101 is part of a standard silicon-on-insulator (SOI) configuration, and thus is disposed on a buried oxide (BOX) layer 120. Thus, FET 100 is an SOI FET. FET 100 includes a gate 102 and spacers 108, 109 on opposing sides of gate 102, all of which are disposed on silicon layer 101. Gate 102 may be a conductive material, such as polysilicon. Spacers 108, 109 may be an insulating material, such as an oxide or silicon nitride.

FET 100 further includes a doped source extension region 103, a doped drain extension region 104, a body region 105, and doped deep source and drain regions 106, 107 outside of source/drain extension regions 103, 104, disposed in silicon layer 101 roughly as shown. Such a FET configuration is well-known. An insulating layer (not shown) such as a tensile or compressive stress liner (for instance, silicon nitride) may also cover FET 100 including gate 102 and spacers 108, 109. The semiconductor device typically includes other circuit elements in addition to FET 100, also disposed in and/or on silicon layer 101.

Various electrical currents may flow through FET 100 depending upon the relative voltages of portions of FET 100. Three currents are shown in FIG. 1. A forward junction current IF flows from body region 105 to deep drain region 107 and/or drain extension region 104. A reverse junction current IR flows from deep source region 106 and/or source extension region 103 into body region 105. A gate current Igb flows from gate 102 into body region 105. The total current flowing into body region 105 will equal the total current flowing out of body region 105. Thus, the following equation holds for any partially-depleted SOI FET:
Igb(−Vb)+IR(Vb−Vdd)=IF(Vb) (Equation 1),
where the dependencies of each current are shown in parentheses. For example, Equation 1 indicates that reverse junction current IR depends upon the difference between body voltage Vb and drain voltage Vdd.

Since gate current Igb is very small compared with currents reverse junction current IR and forward junction current IF, Equation 1 may be approximated with the following equation:
IR(Vb−Vdd)≈IF(Vb) (Equation 2).

FIG. 2 shows an illustrative approximate relationship between reverse junction current IR and forward junction current IF across a P/N junction at a given body voltage Vb. As can be seen, this relationship is consistent with Equation 2. For example, for any drain voltage Vdd, reverse junction current IR approximately equals forward junction current IF.

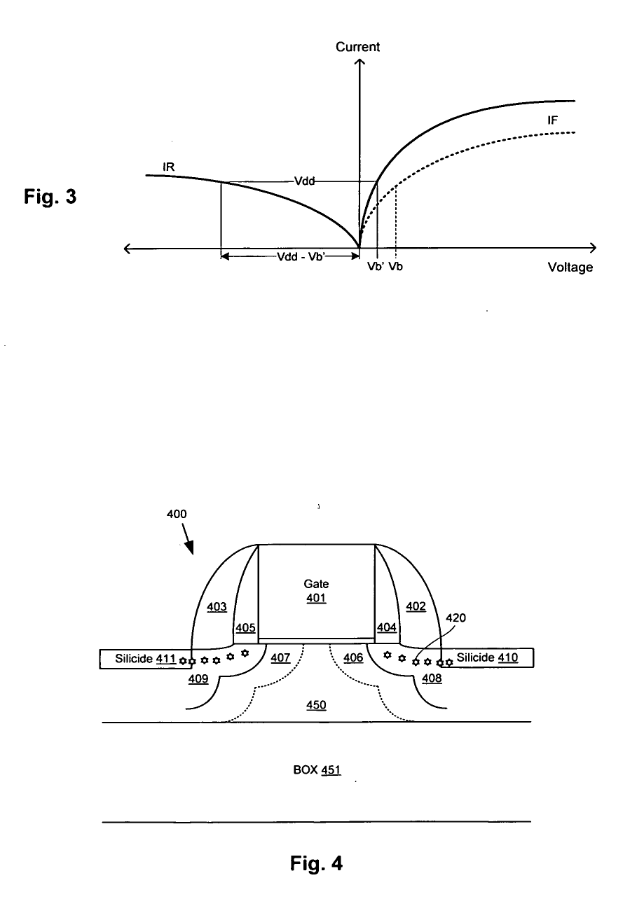

FIG. 3 shows the effect of lowering the body voltage. The broken curve in FIG. 3 indicates the forward junction current IF curve with the original body voltage Vb of FIG. 2, and the solid curve in this figure indicates the forward junction current IF curve with a relatively lower body voltage Vb′. Lowering the body voltage to Vb′ has the effect of raising the forward junction current IF curve, as shown, without affecting (or substantially affecting) the reverse junction current IR curve. This means that, FET 100, the turn-on threshold voltage Vth is increased, thereby lowering the off current.

Thus, forward junction current IF and reverse junction current IR are the main factors in determining body voltage Vb. When reverse junction current IR becomes large, more current flows from the drain into the body, and so body voltage Vb also increases. In addition, as the device is scaled down, well concentration increases. This is particularly noticeable when gate lengths are below 100 nm, where well concentrations can be 1e18 cm-3 or more. This high well concentration results in a high reverse junction current IR and a high body voltage Vb at the off state, thus causing DIBL to be even worse at smaller scales.

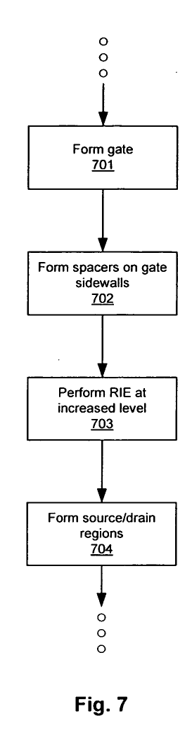

Referring to FIGS. 4 and 7, an illustrative method for manufacturing a partially-depleted SOI FET having a relatively lower body voltage will now be discussed at various points during manufacturing. In step 701, a conductive gate 401 (such as a polysilicon gate) may be formed, such as in a traditional manner, on a silicon layer 450. Silicon layer 450 may be a standard SOI silicon layer such that it is disposed on a buried oxide (BOX) layer 451. A gate oxide or other insulating layer may also be formed between gate 401 and silicon layer 450.

Next, in step 702, another insulating layer may be formed on silicon layer 450 and gate 401, which when partially removed will form offset spacers 404, 405 on opposing sidewalls of gate 401. Spacers 404, 405 may be of any insulating material, such as an oxide or silicon nitride.

Once the insulating layer has been formed over silicon layer 450 and gate 401, the insulating layer may be etched away using traditional lithographic processes. For instance, reactive ion etching (RIE) of the spacer material layer may be performed. To achieve the appropriate amount of etching, traditionally RIE is performed for an amount of time necessary to etch down to the upper surface of silicon layer 450, and then RIE is performed for an additional 20% of this amount of time. Thus, a minor amount of over-etching is performed.

However, in step 703, even more over-etching is performed, thus etching even more of silicon layer 450. Thus, RIE may be performed for an amount of time necessary to etch down to the upper surface of silicon layer 450, and then RIE is continued (or otherwise additionally performed) for more than an additional 20% of this amount of time. This over-etching step damages, in effect, an upper portion of silicon layer 450 and causes carrier traps 420 to be formed in the upper portions of silicon layer 450.

Next, source and drain regions 408, 409 are formed, such as in a conventional manner. It may be desirable to cause carrier traps 420 to be mainly formed only in source/drain regions 408, 409, but not also in (or substantially not in) depletion regions 406 and 407 as has traditionally been the case using Xe implanting. To achieve this location of carrier traps 420 substantially only in source/drain regions 408, 409, the amount of time that RIE is performed may be that necessary to reach the upper surface of silicon layer 450, and then RIE is continued (or otherwise additionally performed) for an additional time period, such as for an additional 50% to 150% of the original RIE time period, or for example approximately 100% or more of the original RIE time period. In the latter case, this means that, for example, RIE may be performed for at least twice the time necessary to reach the upper surface of silicon layer 450. By performing this extra over-etching, a step (the Xe implant step) may actually be removed from the manufacturing process, thus potentially speeding up and/or reducing the cost of manufacturing.

Silicide regions 410, 411, as well as outer spacers 402, 403, may also be formed on opposing sides of gate 401, such as in a conventional manner. Where silicide regions 410, 411 are formed and carrier traps 420 are disposed mainly in neutral source/drain regions 411, 412 but not substantially in depletion regions 406, 407, carrier traps 420 may be located mainly between silicide regions 410, 411 and gate 401, and also possibly within silicide regions 410, 411.

As a result of this manufacturing method, improved partially-depleted SOI FETs may be created. For instance, such a FET may be created having a gate length of less than 100 nm and an IR/IF ratio of less than 0.5, where IR is the reverse junction current at the power supply voltage and IF is the forward current at 0.4 volts. Also, in such a FET, IR in that ratio may be as little as 1e-9 A/um.

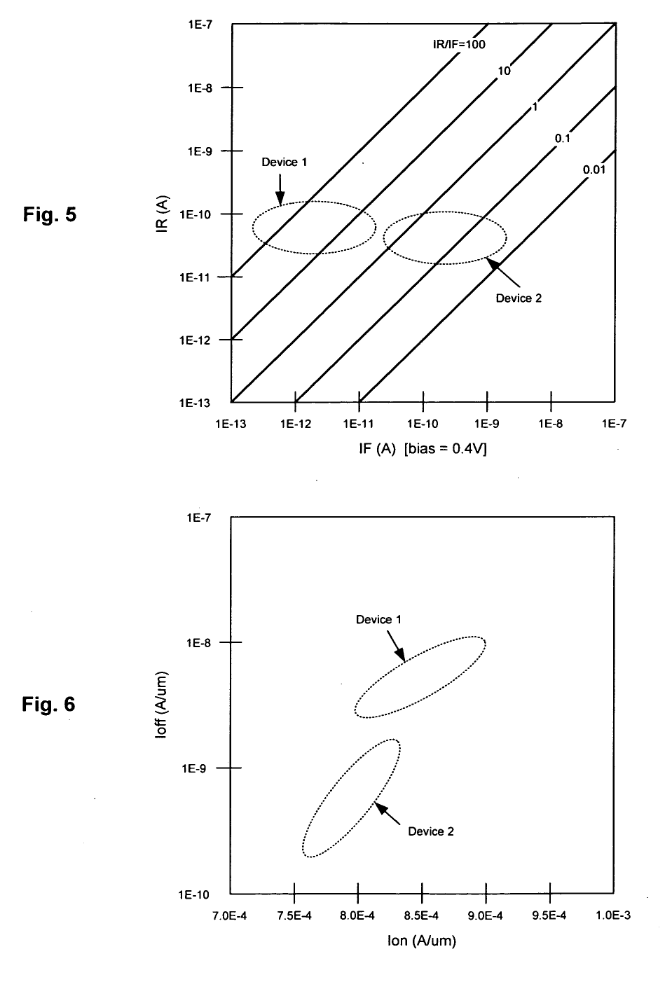

FIGS. 5 and 6 show an affect of changing the IR/IF ratio. Two different illustrative SOI FETs are compared: device 1 and device 2. Device 1 is shown to have an IR/IF ratio of about 50, and device 2 is shown to have an IR/IF ratio of about 0.5. It can be seen from FIG. 6 that device 2 performs better than device 1, in that device 2 has a lower off current (Ioff) at a given drive current (Ion) as compared with device 1.

Thus, an improved way to reduce the off-current in a partially-depleted silicon-on-insulator (SOI) field-effect transistor (FET) has been described, including ways to manufacture an SOI FET having a lower body potential than in previous SOI FETs.

What is claimed is:

1. A method for forming a semiconductor device, comprising:
providing a silicon layer that is disposed on an oxide layer, the silicon layer having a surface;
(a) forming a conductive layer on a portion of the silicon layer;
(b) forming an insulating layer on the conductive layer and on at least a portion of the silicon layer not covered by the conductive layer;
(c) etching the insulating layer for a first period of time sufficient to cause the insulating layer to be etched down to the surface of the silicon layer; and
(d) etching the silicon layer for a second period of time at least as long as the first period of time.

2. The method of claim 1, wherein the conductive layer has opposing sidewalls, and wherein after steps (c) and (d) are performed, a portion of the insulating layer remains disposed on the opposing sidewalls of the conductive layer.

3. The method of claim 1, wherein the conductive layer has opposing sidewalls located less than 100 nm from each other.

4. The method of claim 1, further including implanting ions in the silicon layer on opposing sides of the conductive layer.

5. The method of claim 1, wherein the conductive layer is polysilicon.

6. The method of claim 1, further including forming a silicide layer region in the silicon layer on opposing sides of the conductive layer.

7. The method of claim 1, wherein the steps of etching the insulating layer and etching the silicon layer are performed as a single continuous etching step.

8. The method of claim 1, wherein the second period of time is 150% or less of the first period of time.

9. The method of claim 1, wherein the insulating layer is silicon nitride.

10. A semiconductor device, comprising a field effect transistor, the semiconductor device comprising:
an oxide layer;
a silicon layer disposed on the oxide layer;
a gate of the field effect transistor disposed on the silicon layer;
a source region and a drain region of the field effect transistor disposed in the silicon layer and on opposing sides of the gate; and
an insulating spacer disposed on each of opposing sidewalls of the gate,
wherein a ratio of a reverse junction current of the field effect transistor at a power supply voltage to a forward current of the field effect transistor at 0.4 volts is less than 0.5.

11. The semiconductor device of claim 10, wherein the reverse junction current is less than 1e-9 A/um.

12. The semiconductor device of claim 10, wherein the gate has a length between the opposing sidewalls of less than 100 nm.

13. The semiconductor device of claim 10, wherein carrier traps are disposed mainly in the source and drain regions.

14. The semiconductor device of claim 10, further including a silicide region disposed on the silicon layer on each of opposing sides of the gate, wherein carrier traps are disposed mainly between the silicide regions and the gate.

15. The semiconductor device of claim 10, wherein the gate is polysilicon.

16. The semiconductor device of claim 10, wherein the insulating spacer is silicon nitride.

17. A method for forming a semiconductor device having a field effect transistor, the method comprising:
providing a silicon layer that is disposed on an oxide layer, the silicon layer having a surface;
(a) forming a polysilicon gate of the field effect transistor on a portion of the silicon layer, the gate having opposing sidewalls less than 100 nm apart;
(b) forming an insulating layer on the gate and on at least a portion of the silicon layer not covered by the gate; and
(c) etching the insulating layer and the silicon layer by an amount sufficient to introduce carrier traps in the silicon layer,
wherein a ratio of a reverse junction current of the field effect transistor at a power supply voltage to a forward current of the field effect transistor at 0.4 volts is less than 0.5.

18. The method of claim 17, wherein the reverse junction current is less than 1e-9 A/um.

19. The method of claim 17, wherein the step of etching includes etching the insulating layer for a first period of time sufficient to cause the insulating layer to be etched down to the surface of the silicon layer, and etching the silicon layer for a second period of time at least as long as the first period of time.

20. The method of claim 17, wherein the step of etching includes etching the insulating layer for a first period of time sufficient to cause the insulating layer to be etched down to the surface of the silicon layer, and etching the silicon layer for a second period of time that is in a range of 50% and 150% as long as the first period of time.
